(19) United States
(12) Patent Application Publication
(10) Pub. No.: US 2024/0063217 A1
(43) Pub. Date: Feb. 22, 2024

(54) SEMICONDUCTOR STRUCTURES WITH BACK SIDE TRANSISTOR DEVICES

(71) Applicant: International Business Machines Corporation, Armonk, NY (US)

(72) Inventors: Ruilong Xie, Niskayuna, NY (US); Julien Frougier, Albany, NY (US); Kangguo Cheng, Schenectady, NY (US); Chanro Park, Clifton Park, NY (US); Min Gyu Sung, Latham, NY (US)

(21) Appl. No.: 17/889,615

(22) Filed: Aug. 17, 2022

(51) Int. Cl. H01L 27/06; H01L 29/06; H01L 29/423; H01L 29/417; H01L 29/786; H01L 29/775; H01L 21/78; H01L 21/822; H01L 21/8234; H01L 29/66

(52) U.S. Cl. CPC H01L 27/0694; H01L 29/0673; H01L 29/42392; H01L 29/41733; H01L 29/78696; H01L 29/775; H01L 21/7806; H01L 21/8221; H01L 21/823412; H01L 21/823475; H01L 21/823481; H01L 29/66742; H01L 29/66439

(57) ABSTRACT

A semiconductor structure comprises one or more transistor devices on a first side of the semiconductor structure, one or more transistor devices on a second side of the semiconductor structure, the second side being opposite the first side, and a dielectric isolation layer separating the one or more transistor devices on the first side of the semiconductor structure from the one or more transistor devices on the second side of the semiconductor structure. The one or more transistor devices on the second side of the semiconductor structure comprise channel layers on one side of the dielectric isolation layer and source/drain regions that are independent of source/drain regions of the one or more transistor devices on the first side of the semiconductor structure.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments of the invention provide techniques for forming semiconductor structures with back side transistor devices.

In one embodiment, a semiconductor structure comprises one or more transistor devices on a first side of the semiconductor structure, one or more transistor devices on a second side of the semiconductor structure, the second side being opposite the first side, and a dielectric isolation layer separating the one or more transistor devices on the first side of the semiconductor structure from the one or more transistor devices on the second side of the semiconductor structure. The one or more transistor devices on the second side of the semiconductor structure comprise channel layers on one side of the dielectric isolation layer and source/drain regions that are independent of source/drain regions of the one or more transistor devices on the first side of the semiconductor structure.

In another embodiment, an integrated circuit comprises a semiconductor structure comprising one or more transistor devices on a first side of the semiconductor structure, one or more transistor devices on a second side of the semiconductor structure, the second side being opposite the first side, and a dielectric isolation layer separating the one or more transistor devices on the first side of the semiconductor structure from the one or more transistor devices on the second side of the semiconductor structure. The one or more transistor devices on the second side of the semiconductor structure comprise channel layers on one side of the dielectric isolation layer and source/drain regions that are independent of source/drain regions of the one or more transistor devices on the first side of the semiconductor structure

In another embodiment, a method comprises forming one or more transistor devices on a first side of a semiconductor structure, forming one or more transistor devices on a second side of the semiconductor structure, the second side being opposite the first side, and forming a dielectric isolation layer separating the one or more transistor devices on the first side of the semiconductor structure from the one or more transistor devices on the second side of the semiconductor structure. The one or more transistor devices on the second side of the semiconductor structure comprise channel layers on one side of the dielectric isolation layer and source/drain regions that are independent of source/drain regions of the one or more transistor devices on the first side of the semiconductor structure.

These and other features and advantages of embodiments described herein will become more apparent from the accompanying drawings and the following detailed description.

### BRIEF DESCRIPTION OF THE DRAWINGS

FIG. 1A depicts a first side cross-sectional view of a structure following formation of a nanosheet stack over a substrate, according to an embodiment of the invention.

FIG. 1B depicts a second side cross-sectional view of a structure following formation of a nanosheet stack over a substrate, according to an embodiment of the invention.

FIG. 1C depicts a top-down view of a structure following formation of a nanosheet stack over a substrate, according to an embodiment of the invention.

FIG. 2A depicts a first side cross-sectional view of the structure of FIGS. 1A-1C following nanosheet patterning, formation of shallow trench isolation regions, and patterning of a dummy gate layer, according to an embodiment of the invention.

FIG. 2B depicts a second side cross-sectional view of the structure of FIGS. 1A-1C following the nanosheet patterning, the formation of the shallow trench isolation regions, and the patterning of the dummy gate layer, according to an embodiment of the invention.

FIG. 2C depicts a top-down view of the structure of FIGS. 1A-1C following the nanosheet patterning, the formation of the shallow trench isolation regions, and the patterning of the dummy gate layer, according to an embodiment of the invention.

FIG. 3A depicts a first side cross-sectional view of the structure of FIGS. 2A-2C following removal of a sacrificial layer, according to an embodiment of the invention.

FIG. 3B depicts a second side cross-sectional view of the structure of FIGS. 2A-2C following the removal of the sacrificial layer, according to an embodiment of the invention.

FIG. 3C depicts a top-down view of the structure of FIGS. 2A-2C following the removal of the sacrificial layer, according to an embodiment of the invention.

FIG. 4A depicts a first side cross-sectional view of the structure of FIGS. 3A-3C following conformal deposition and etching of spacer material, according to an embodiment of the invention.

FIG. 4B depicts a second side cross-sectional view of the structure of FIGS. 3A-3C following the conformal deposition and the etching of the spacer material, according to an embodiment of the invention.

FIG. 4C depicts a top-down view of the structure of FIGS. 3A-3C following the conformal deposition and the etching of the spacer material, according to an embodiment of the invention.

FIG. 5A depicts a first side cross-sectional view of the structure of FIGS. 4A-4C following recess of sacrificial layers, formation of inner spacers, formation of source/drain regions and formation of an interlayer dielectric layer, according to an embodiment of the invention.

FIG. 5B depicts a second side cross-sectional view of the structure of FIGS. 4A-4C following the recess of the sacrificial layers, the formation of the inner spacers, the formation of the source/drain regions and the formation of the interlayer dielectric layer, according to an embodiment of the invention.

FIG. 5C depicts a top-down view of the structure of FIGS. 4A-4C following the recess of the sacrificial layers, the formation of the inner spacers, the formation of the source/drain regions and the formation of the interlayer dielectric layer, according to an embodiment of the invention.

FIG. 6A depicts a first side cross-sectional view of the structure of FIGS. 5A-5C following removal of the dummy gate layer, removal of remaining portions of the sacrificial layers, formation of a gate stack layer, formation of middle-of-line contacts, formation of front side back-end-of-line interconnects, and bonding to a carrier wafer, according to an embodiment of the invention.

FIG. 6B depicts a second side cross-sectional view of the structure of FIGS. 5A-5C following the removal of the dummy gate layer, the removal of the remaining portions of the sacrificial layers, the formation of the gate stack layer, the formation of the middle-of-line contacts, the formation of the front side back-end-of-line interconnects, and the bonding to the carrier wafer, according to an embodiment of the invention.

FIG. 6C depicts a top-down view of the structure of FIGS. 5A-5C following the removal of the dummy gate layer, the removal of the remaining portions of the sacrificial layers, the formation of the gate stack layer, the formation of the middle-of-line contacts, the formation of the front side back-end-of-line interconnects, and the bonding to the carrier wafer, according to an embodiment of the invention.

FIG. 6D depicts a third side cross-sectional view of the structure of FIGS. 5A-5C following the removal of the dummy gate layer, the removal of the remaining portions of the sacrificial layers, the formation of the gate stack layer, an alternate formation of the middle-of-line contacts, the formation of the front side back-end-of-line interconnects, and the bonding to the carrier wafer, according to an embodiment of the invention.

FIG. 6E depicts a fourth side cross-sectional view of the structure of FIGS. 5A-5C following the removal of the dummy gate layer, the removal of the remaining portions of the sacrificial layers, the formation of the gate stack layer, the alternate formation of the middle-of-line contacts, the formation of the front side back-end-of-line interconnects, and the bonding to the carrier wafer, according to an embodiment of the invention.

FIG. 7A depicts a first side cross-sectional view of the structure of FIGS. 6A-6E following a wafer flip and removal of portions of the substrate stopping on an etch stop layer, according to an embodiment of the invention.

FIG. 7B depicts a second side cross-sectional view of the structure of FIGS. 6A-6E following the wafer flip and the removal of the portions of the substrate stopping on the etch stop layer, according to an embodiment of the invention.

FIG. 7C depicts a top-down view of the structure of FIGS. 6A-6E following the wafer flip and the removal of the portions of the substrate stopping on the etch stop layer, according to an embodiment of the invention.

FIG. 7D depicts a third side cross-sectional view of the structure of FIGS. 6A-6E following the wafer flip and the removal of the portions of the substrate stopping on the etch stop layer, according to an embodiment of the invention.

FIG. 7E depicts a fourth side cross-sectional view of the structure of FIGS. 6A-6E following the wafer flip and the removal of the portions of the substrate stopping on the etch stop layer, according to an embodiment of the invention.

FIG. 8A depicts a first side cross-sectional view of the structure of FIGS. 7A-7E following removal of the etch stop layer and remaining portions of the substrate, according to an embodiment of the invention.

FIG. 8B depicts a second side cross-sectional view of the structure of FIGS. 7A-7E following the removal of the etch stop layer and the remaining portions of the substrate, according to an embodiment of the invention.

FIG. 8C depicts a top-down view of the structure of FIGS. 7A-7E following the removal of the etch stop layer and the remaining portions of the substrate, according to an embodiment of the invention.

FIG. 8D depicts a third side cross-sectional view of the structure of FIGS. 7A-7E following the removal of the etch stop layer and the remaining portions of the substrate, according to an embodiment of the invention.

FIG. 8E depicts a fourth side cross-sectional view of the structure of FIGS. 7A-7E following the removal of the etch stop layer and the remaining portions of the substrate, according to an embodiment of the invention.

FIG. 9A depicts a first side cross-sectional view of the structure of FIGS. 8A-8E following removal of a sacrificial layer, according to an embodiment of the invention.

FIG. 9B depicts a second side cross-sectional view of the structure of FIGS. 8A-8E following the removal of the sacrificial layer, according to an embodiment of the invention.

FIG. 9C depicts a top-down view of the structure of FIGS. 8A-8E following the removal of the sacrificial layer, according to an embodiment of the invention.

FIG. 9D depicts a third side cross-sectional view of the structure of FIGS. 8A-8E following the removal of the sacrificial layer, according to an embodiment of the invention.

FIG. 9E depicts a fourth side cross-sectional view of the structure of FIGS. 8A-8E following the removal of the sacrificial layer, according to an embodiment of the invention.

FIG. 10A depicts a first side cross-sectional view of the structure of FIGS. 9A-9E following selective formation of a back side transistor, according to an embodiment of the invention.

FIG. 10B depicts a second side cross-sectional view of the structure of FIGS. 9A-9E following the selective formation of the back side transistor, according to an embodiment of the invention.

FIG. 10C depicts a top-down view of the structure of FIGS. 9A-9E following the selective formation of the back side transistor, according to an embodiment of the invention.

FIG. 10D depicts a third side cross-sectional view of the structure of FIGS. 9A-9E following the selective formation of the back side transistor, according to an embodiment of the invention.

FIG. 10E depicts a fourth side cross-sectional view of the structure of FIGS. 9A-9E following the selective formation of the back side transistor, according to an embodiment of the invention.

FIG. 11A depicts a first side cross-sectional view of the structure of FIGS. 10A-10E following formation of a back side interlayer dielectric layer and back side contacts, according to an embodiment of the invention.

FIG. 11B depicts a second side cross-sectional view of the structure of FIGS. 10A-10E following the formation of the back side interlayer dielectric layer and the back side contacts, according to an embodiment of the invention.

FIG. 11C depicts a top-down view of the structure of FIGS. 10A-10E following the formation of the back side interlayer dielectric layer and the back side contacts, according to an embodiment of the invention.

FIG. 11D depicts a third side cross-sectional view of the structure of FIGS. 10A-10E following the formation of the back side interlayer dielectric layer and the back side contacts, according to an embodiment of the invention.

FIG. 11E depicts a fourth side cross-sectional view of the structure of FIGS. 10A-10E following the formation of the back side interlayer dielectric layer and the back side contacts, according to an embodiment of the invention.

FIG. 12A depicts a first side cross-sectional view of the structure of FIGS. 11A-11E following formation of back side back-end-of-line interconnects, according to an embodiment of the invention.

FIG. 12B depicts a second side cross-sectional view of the structure of FIGS. 11A-11E following the formation of the back side back-end-of-line interconnects, according to an embodiment of the invention.

FIG. 12C depicts a top-down view of the structure of FIGS. 11A-11E following the formation of the back side back-end-of-line interconnects, according to an embodiment of the invention.

FIG. 12D depicts a third side cross-sectional view of the structure of FIGS. 11A-11E following the formation of the back side back-end-of-line interconnects, according to an embodiment of the invention.

FIG. 12E depicts a fourth side cross-sectional view of the structure of FIGS. 11A-11E following the formation of the back side back-end-of-line interconnects, according to an embodiment of the invention.

FIG. 13 depicts an integrated circuit comprising one or more semiconductor structures with back side power distribution networks, according to an embodiment of the invention.

### DETAILED DESCRIPTION

Illustrative embodiments of the invention may be described herein in the context of illustrative methods for forming semiconductor structures with back side transistor devices, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm and beyond. A general process flow for formation of a nanosheet stack involves removing sacrificial layers, which may be formed of silicon germanium (SiGe), between sheets of channel material, which may be formed of silicon (Si).

In some structures, it is desirable to integrate one or more transistors with single crystal channels (e.g., single crystal Si) on the back side of a wafer (e.g., where the wafer includes one or more other front side transistor or logic devices, such as FinFET or nanosheet FET devices). Single crystal Si channel transistors advantageously have improved performance relative to back-end-of-line (BEOL) thin film transistors (TFTs). Various semiconductor structures include back side power distribution networks (BSPDNs). Conventional structures may include bulk Si everywhere on the back side of a wafer, for both a BSPDN and back side transistors (e.g., back side TFTs). Illustrative embodiments provide approaches which provide a bulk Si presence only for regions of a wafer that have back side transistor devices, with the bulk Si being removed for active or logic devices which are supplied power from back side contacts. Such structures advantageously enable a co-integration scheme with a BSPDN.

A process flow for the co-integration scheme may include forming a bottom dielectric insulator (BDI) layer underneath nanosheet channels, and above a thin single-crystal channel layer. One or more front side transistors (e.g., nanosheet FETs) are then formed using the nanosheet channels. The wafer or structure may then be flipped, followed by removing portions of the substrate to reveal the thin single-crystal channel layer. Back side transistors may then be formed using the thin single-crystal Si channel layer, where the back side transistors are separated from the front side transistors by the BDI layer. Back side transistors may be formed on only some parts or regions of the structure. In other regions, the thin single-crystal Si channel layer may be removed in order to form back side contacts to the front side transistors.

Semiconductor or microelectronic structures may include one or more back side transistors formed under one or more front side transistors. The back side transistors may be long channel devices, with relaxed gate pitch and a thick gate oxide. A dielectric isolation layer (e.g., a BDI layer) in the structure separates the back side and front side transistors. The back side transistors may be formed over some regions of the structures, with back side contacts being formed to source/drain regions of front side transistors in other regions of the structures.

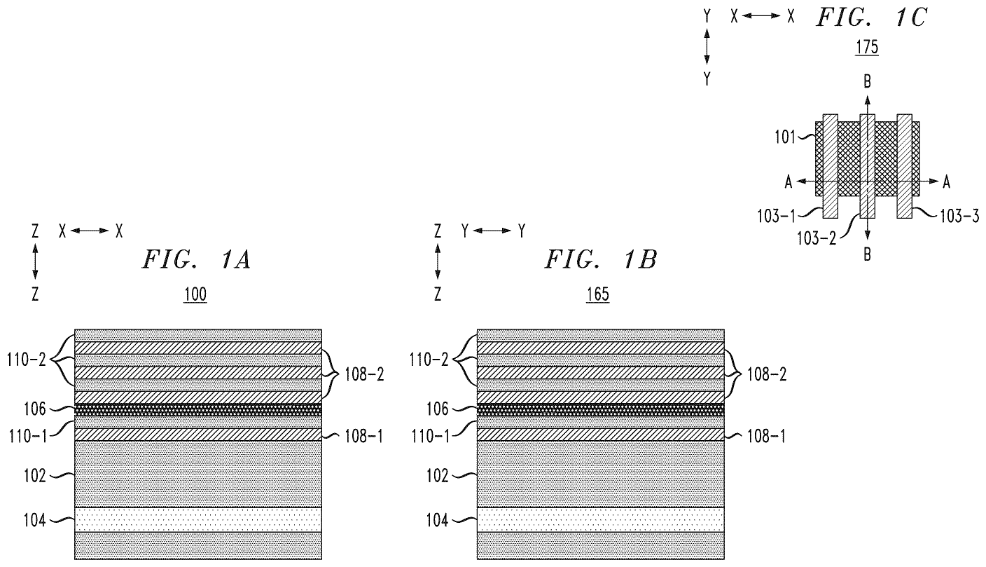

FIGS. 1A-12E show a process flow for forming semiconductor structures with back side transistors.

FIG. 1A shows a first side cross-sectional view 100 of a structure, following formation of a nanosheet stack over a substrate 102. FIG. 1B shows a second side cross-sectional view 165 of the structure, and FIG. 1C shows a top-down view 175 of the structure. The top-down view 175 of FIG. 1C shows an active region 101 where gate structures 103-1, 103-2 and 103-3 will be formed. The first side cross-sectional view 100 of FIG. 1A is taken along the line A-A in the top-down view 175 of FIG. 1C (e.g., across the gate structures 103-1, 103-2 and 103-3), and the second side cross-sectional view 165 of FIG. 1B is taken along the line B-B in the top-down view 175 of FIG. 1C (e.g., along the gate structure 103-2).

The substrate 102 may be formed of any suitable semiconductor structure, including various silicon-containing materials including but not limited to Si, SiGe, silicon germanium carbide (SiGeC), silicon carbide (SiC) and multi-layers thereof. Although silicon is the predominantly used semiconductor material in wafer fabrication, alternative semiconductor materials can be employed as additional layers, such as, but not limited to, germanium (Ge), gallium arsenide (GaAs), gallium nitride (GaN), SiGe, cadmium telluride (CdTe), zinc selenide (ZnSe), etc.

An etch stop layer 104 is formed in the substrate 102. The etch stop layer 104 may comprise a buried oxide (BOX) layer or SiGe, or another suitable material such as a III-V semiconductor epitaxial layer. The etch stop layer 104 may have a height (in the Z direction) in the range of 10 to 30 nm.

A nanosheet stack is formed over the substrate 102, where the nanosheets include a sacrificial layer 106, sacrificial layers 108-1 and 108-2 (collectively, sacrificial layers 108), and channel layers 110-1 and 110-2. The channel layer 110-1 may be used for one or more back side transistors, while the channel layers 110-2 may be used for one or more front side transistors.

The sacrificial layers 106 and 108 are illustratively formed of different sacrificial materials, such that they may be etched or otherwise removed selective to one another. In some embodiments, both the sacrificial layers 106 and sacrificial layers 108 are formed of SiGe, but with different percentages of Ge. For example, the sacrificial layer 106 may have a relatively higher percentage of Ge (e.g., 55% Ge), and the sacrificial layers 108 may have a relatively lower percentage of Ge (e.g., 25% Ge). Other combinations of different sacrificial materials may be used in other embodiments. The sacrificial layers 106 and 108 may each have a thickness (in the Z direction) in the range of 6-15 nm.

The channel layers 110 may be formed of Si or another suitable material (e.g., a material similar to that used for the substrate 102). Each of the channel layers 110 may have a thickness (in the Z direction) in the range of 4-10 nm. Here, the channel layer 110-1 is illustratively a single-crystal channel layer (e.g., single-crystal Si), and the channel layers 110-2 provide nanosheet channels for front side nanosheet FETs.

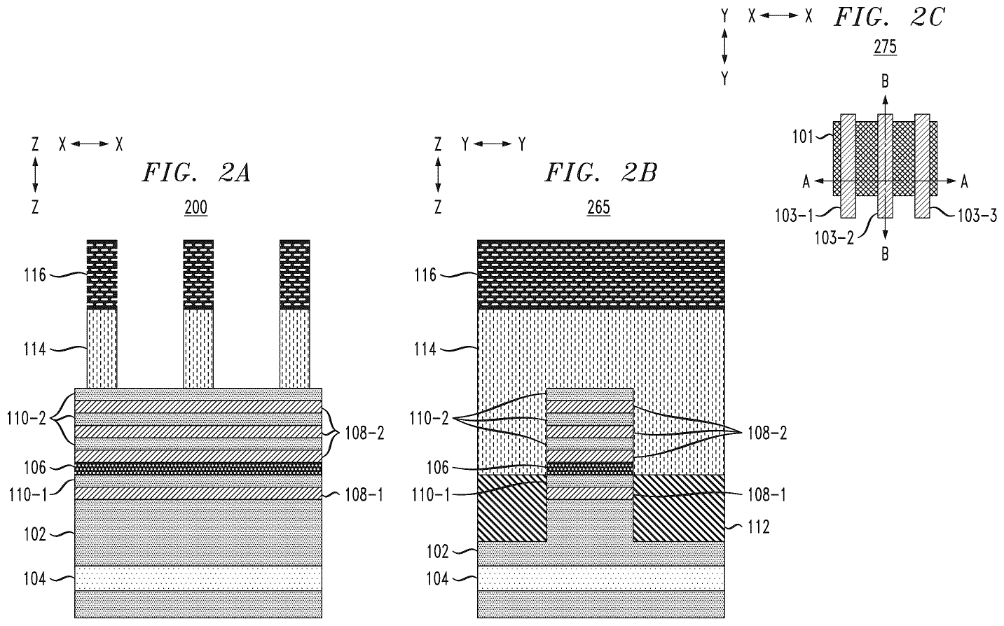

FIG. 2A shows a first side cross-sectional view 200 of the structure of FIGS. 1A-1C following nanosheet patterning, formation of STI regions 112 and patterning of a dummy gate layer 114. FIG. 2B shows a second side cross-sectional view 265 of the structure of FIGS. 1A-1C following the nanosheet patterning, the formation of the STI regions 112, and the patterning of the dummy gate layer 114. FIG. 2C shows a top-down view 275 of the structure of FIGS. 1A-1C following the nanosheet patterning, the formation of the STI regions 112, and the patterning of the dummy gate layer 114. The first side cross-sectional view 200 of FIG. 2A is taken along the line A-A in the top-down view 275 of FIG. 2C, and the second side cross-sectional view 265 of FIG. 2B is taken along the line B-B in the top-down view 275 of FIG. 2C.

The STI regions 112 may be formed by patterning a masking layer over the structure of FIGS. 1A-1C, followed by etching exposed portions of the sacrificial layers 106 and 108, the channel layers 110, and through a portion of the substrate 102 as illustrated in FIG. 2B. The STI regions 112 may be formed of a dielectric material such as silicon dioxide (SiO₂), silicon oxycarbide (SiOC), silicon oxynitride (SiON), etc. The STI regions 112 may have a height (in the Z direction) in the range of 20 to 100 nm.

The dummy gate layer 114 may be filled over the structure, followed by patterning using a gate hard mask (HM) layer 116. The dummy gate layer 114 may be formed by blanket deposition of material of the dummy gate layer 114 (e.g., amorphous silicon (a-Si) or amorphous silicon germanium (a-SiGe) over a thin SiO₂ or titanium nitride (TiN) layer, or another suitable material) and material of the gate HM layer 116 (e.g., silicon nitride (SiN), a multi-layer of SiN and SiO₂, or another suitable material), followed by lithographic processing to result in the patterned gate HM layer 116 and underlying dummy gate layer 114 as shown in FIGS. 2A and 2B. The dummy gate layer 114 may have a height (in the Y direction) in the range of 30 to 100 nm and a width (in the X direction) in the range of 12 to 100 nm. The gate HM layer 116 may have a height (in the Y direction) in the range of 20 to 100 nm, and a width (in the X direction) matching that of the underlying dummy gate layer 114.

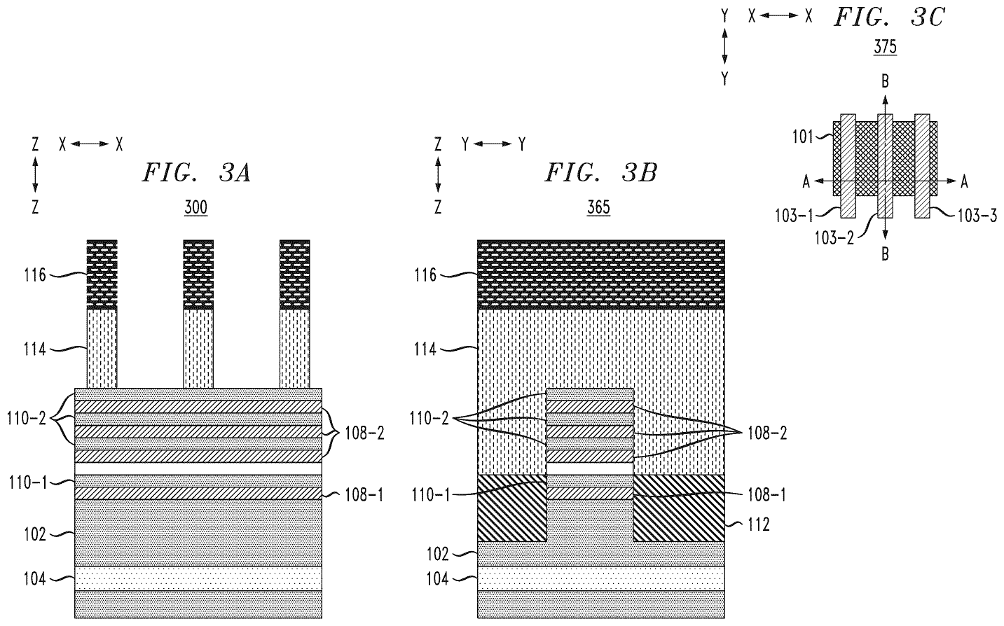

FIG. 3A shows a first side cross-sectional view 300 of the structure of FIGS. 2A-2C following removal of the sacrificial layer 106. FIG. 3B shows a second side cross-sectional view 365 of the structure of FIGS. 2A-2C following the removal of the sacrificial layer 106. FIG. 3C shows a top-down view 375 of the structure of FIGS. 2A-2C following the removal of the sacrificial layer 106. The first side cross-sectional view 300 of FIG. 3A is taken along the line A-A in the top-down view 375 of FIG. 3C, and the second side cross-sectional view 365 of FIG. 3B is taken along the line B-B in the top-down view 375 of FIG. 3C.

The sacrificial layer 106 may be removed using a selective etch process, which removes the material of the sacrificial layer 106 (e.g., e.g., 55% Ge) selective to the material of the sacrificial layers 108 (e.g., 25% Ge).

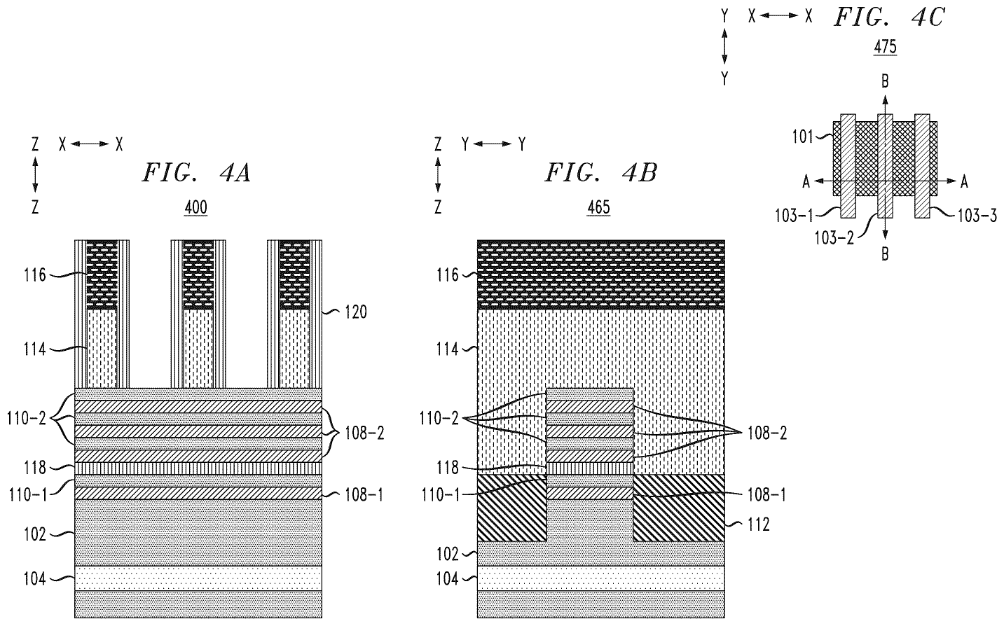

FIG. 4A shows a first side cross-sectional view 400 of the structure of FIGS. 3A-3C following conformal deposition and etching of spacer material. FIG. 4B shows a second side cross-sectional view 465 of the structure of FIGS. 3A-3C following the conformal deposition and etching of the spacer material. FIG. 4C shows a top-down view 475 of the structure of FIGS. 3A-3C following the conformal deposition and etching of the spacer material. The first side cross-sectional view 400 of FIG. 4A is taken along the line A-A in the top-down view 475 of FIG. 4C, and the second side cross-sectional view 465 of FIG. 4B is taken along the line B-B in the top-down view 475 of FIG. 4C.

A spacer material (e.g., any suitable insulator, such as SiN, silicon boron carbide nitride (SiBCN), silicon oxycarbonitride (SiOCN), etc.) may be blanket deposited, filling the region exposed by removal of the sacrificial layer 106 and overfilling the structure. The portions of the spacer material filling the region exposed by removal of the sacrificial layer 106 provides a BDI layer 118. The portions of the spacer material that overfill the structure may be etched (e.g., using reactive-ion etching (RIE) or other suitable etch processing) to result in sidewall spacers 120 on sidewalls of the dummy gate layer 114 and gate HM layer 116 as shown in FIG. 4A. The sidewall spacers 120 may have a width (in the X direction) in the range of 5 to 15 nm.

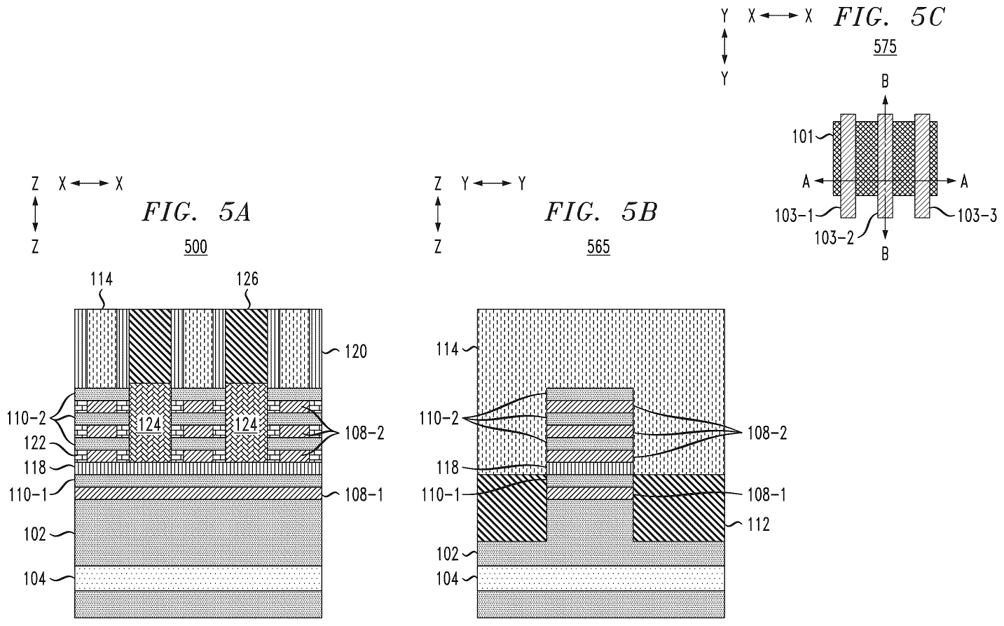

FIG. 5A shows a first side cross-sectional view 500 of the structure of FIGS. 4A-4C following recess or indent of the sacrificial layers 108-2, formation of inner spacers 122, formation of source/drain regions 124, and formation of a front side interlayer dielectric (ILD) layer 126. FIG. 5B shows a second side cross-sectional view 565 of the structure of FIGS. 4A-4C following the recess of the sacrificial layers 108-2, the formation of the inner spacers 122, the formation of the source/drain regions 124, and the formation of the front side ILD layer 126. FIG. 5C shows a top-down view 575 of the structure of FIGS. 4A-4C following the recess of the sacrificial layers 108-2, the formation of the inner spacers 122, the formation of the source/drain regions 124, and the formation of the front side ILD layer 126. The first side cross-sectional view 500 of FIG. 5A is taken along the line A-A in the top-down view 575 of FIG. 5C, and the second side cross-sectional view 565 of FIG. 5B is taken along the line B-B in the top-down view 575 of FIG. 5C.

The sacrificial layers 108-2 may be recessed or indented, followed by formation of the inner spacers 122 in the indent regions formed by the recess of the sacrificial layers 108-2. Next, portions of the nanosheet stack which are not covered by the gate HM layer 116 or the sidewall spacers 120 are etched through to the BDI layer 118. The source/drain regions 124 are then formed. The front side ILD layer 126 is filled over the source/drain regions 124 between the sidewall spacers 120.

The inner spacers 122 may be formed to fill indent spaces (e.g., resulting from indent etches of the sacrificial layers 108). The inner spacers 122 may be formed of SiN or another suitable material such as SiBCN, SiCO, SiOCN, etc. The inner spacers 122 may have widths (in the X direction) in the range of 5 to 15 nm, and may have heights (in the Z direction) matching that of the sacrificial layers 108.

The source/drain regions 124 may be formed using epitaxial growth processes, and thus may also be referred to as epitaxial layers 124. The source/drain regions 124 may be suitably doped, such as using ion implantation, gas phase doping, plasma doping, plasma immersion ion implantation, cluster doping, infusion doping, liquid phase doping, solid phase doping, etc. N-type dopants may be selected from a group of phosphorus (P), arsenic (As) and antimony (Sb), and p-type dopants may be selected from a group of boron (B), boron fluoride (BF₂), gallium (Ga), indium (In), and thallium (Tl). The source/drain regions 124 may be formed using epitaxial growth processes. In some embodiments, the epitaxy process comprises in-situ doping (dopants are incorporated in epitaxy material during epitaxy). Epitaxial materials may be grown from gaseous or liquid precursors. Epitaxial materials may be grown using vapor-phase epitaxy (VPE), molecular-beam epitaxy (MBE), liquid-phase epitaxy (LPE), rapid thermal chemical vapor deposition (RTCVD), metal organic chemical vapor deposition (MOCVD), ultra-high vacuum chemical vapor deposition (UHVCVD), low-pressure chemical vapor deposition (LPCVD), limited reaction processing CVD (LRPCVD), or other suitable processes. Epitaxial silicon, silicon germanium (SiGe), germanium (Ge), and/or carbon doped silicon (Si:C) silicon can be doped during deposition (in-situ doped) by adding dopants, such as n-type dopants (e.g., phosphorus or arsenic) or p-type dopants (e.g., boron or gallium), depending on the type of transistor to be formed. The dopant concentration in the source/drain can range from 1×10¹⁹ cm⁻³ to 3×10²¹ cm⁻³, or preferably between 2×10²⁰ cm⁻³ to 3×10²¹ cm⁻³. The source/drain regions 124 may have a width (in the X direction) in the range of 10 to 30 nm.

The front side ILD layer 126 is formed over the top of the source/drain regions 124 between the sidewall spacers 120. The front side ILD layer 126 may be formed of any suitable isolating material, such as SiO₂, SiOC, SiON, etc. The front side ILD layer 126 has a width (in the X direction) which matches that of the source/drain regions 124. The front side ILD layer 126 may be planarized (e.g., using chemical mechanical planarization (CMP) or other suitable processing) such that its top surface is level with the top surface of the dummy gate layer 114 as shown in FIG. 5A.

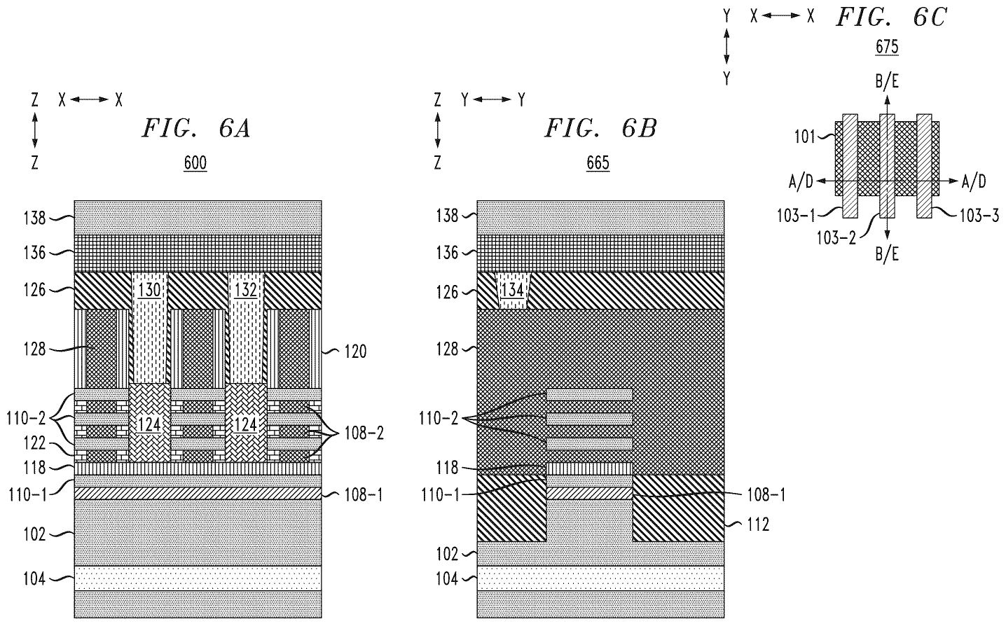

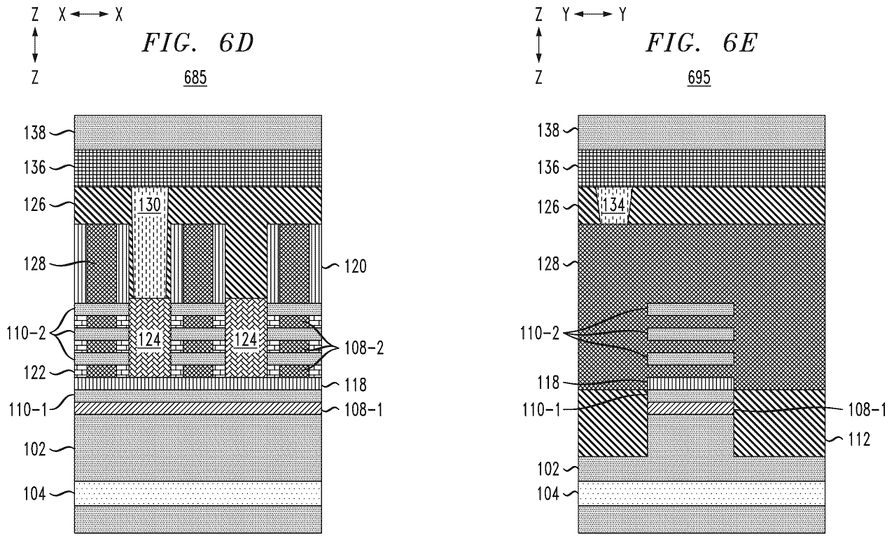

FIG. 6A shows a first side cross-sectional view 600 of the structure of FIGS. 5A-5C following removal of the dummy gate layer 114, removal of remaining portions of the sacrificial layers 108-2, formation of a gate stack layer 128 (e.g., using replacement high-k metal gate (HKMG) processing), formation of middle-of-line (MOL) contacts 130, 132 and 134, formation of BEOL interconnects 136, and bonding of the structure to a carrier wafer 138. FIG. 6B shows a second side cross-sectional view 665 of the structure of FIGS. 5A-5C following the removal of the dummy gate layer 114, the removal of the remaining portions of the sacrificial layers 108-2, the formation of the gate stack layer 128, the formation of the MOL contacts 130, 132 and 134, the formation of the BEOL interconnects 136, and the bonding of the structure to the carrier wafer 138. FIG. 6C shows a top-down view 675 of the structure of FIGS. 5A-5C following the removal of the dummy gate layer 114, the removal of the remaining portions of the sacrificial layers 108-2, the formation of the gate stack layer 128, the formation of the MOL contacts 130, 132 and 134, the formation of the BEOL interconnects 136, and the bonding of the structure to the carrier wafer 138. FIG. 6D shows a third side cross-sectional view 685 of the structure of FIGS. 5A-5C following the removal of the dummy gate layer 114, the removal of the remaining portions of the sacrificial layers 108-2, the formation of the gate stack layer 128, alternate formation of the MOL contacts 130 and 134, the formation of the BEOL interconnects 136, and the bonding of the structure to the carrier wafer 138. FIG. 6E shows a fourth side cross-sectional view 695 of the structure of FIGS. 5A-5C following the removal of the dummy gate layer 114, the removal of the remaining portions of the sacrificial layers 108-2, the formation of the gate stack layer 128, the alternate formation of the MOL contacts 130 and 134, the formation of the BEOL interconnects 136, and the bonding of the structure to the carrier wafer 138. The first side cross-sectional view 600 of FIG. 6A and the third side cross-sectional view 685 of FIG. 6D are taken along the line A/D-A/D in the top-down view 675 of FIG. 6C, while the second side cross-sectional view 665 of FIG. 6B and the fourth side cross-sectional view 695 of FIG. 6E are taken along the line B/E-B/E in the top-down view 675 of FIG. 6C.

As noted above, illustrative embodiments enable flexibility in that certain regions of the structure may have back side transistors formed thereon while other regions of the structure may include back side contacts to the front side transistors. The first and second side cross-sectional views 600 and 665 of FIGS. 6A and 6B (and subsequent similarly-lettered A and B figures) show the regions of the structure where the back side transistors will be formed, while the third and fourth side cross-sectional view 685 and 695 of FIGS. 6D and 6E (and subsequent similarly-letter D and E figures) show the regions of the structure where back side contacts to front side transistors will be formed.

It should be appreciated that the processing shown in FIGS. 6A, 6B, 6D and 6E (and subsequent similarly-lettered A, B, D and E figures) may be performed for the same structure, such as where the processing of FIGS. 6A and 6B (and subsequent similarly-lettered A and B figures) is used for one or more first portions of the structure and the processing of FIGS. 6D and 6E (and subsequent similarly-lettered D and E figures) is used for one or more second portions of the same structure. While for clarity of illustration only one A/D-A/D line and one B/E-B/E line are shown in the top-down view 675 of FIG. 6C (and in subsequent similarly-lettered C figures), the different processing of FIGS. 6A and 6B (and subsequent similarly-lettered A and B figures) and FIGS. 6D and 6E (and subsequent similarly-lettered D and E figures) may be used for different ones of the gate structures 103-1, 103-2 and 103-3, or even along different portions of the length (in the Y direction) of a particular one of the gate structures 103-1, 103-2 and 103-3, in any desired combination.

The dummy gate layer 114 is removed, followed by remaining portions of the sacrificial layers 108-2 (e.g., using SiGe release or other suitable processing). A gate stack layer 128 is then formed using replacement HKMG processing.

The gate stack layer 128 may comprise a gate dielectric layer and a gate conductor layer. The gate dielectric layer may be formed of a high-k dielectric material. Examples of high-k materials include but are not limited to metal oxides such as HfO₂, hafnium silicon oxide (Hf—Si—O), hafnium silicon oxynitride (HfSiON), lanthanum oxide (La₂O₃), lanthanum aluminum oxide (LaAlO₃), zirconium oxide (ZrO₂), zirconium silicon oxide, zirconium silicon oxynitride, tantalum oxide (Ta₂O₅), titanium oxide (TiO₂), barium strontium titanium oxide, barium titanium oxide, strontium titanium oxide, yttrium oxide (Y₂O₃), aluminum oxide (Al₂O₃), lead scandium tantalum oxide, and lead zinc niobate. The high-k material may further include dopants such as lanthanum (La), aluminum (Al), and magnesium (Mg). The gate dielectric layer may have a uniform thickness in the range of 1 nm to 3 nm.

The gate conductor layer may include a metal gate or work function metal (WFM). The WFM for the gate conductor layer may be titanium (Ti), titanium nitride (TiN), tantalum (Ta), tantalum nitride (TaN), aluminum (Al), titanium aluminum (TiAl), titanium aluminum carbon (TiAlC), a combination of Ti and Al alloys, a stack which includes a barrier layer (e.g., of TiN, TaN, etc.) followed by one or more of the aforementioned WFM materials, etc. It should be appreciated that various other materials may be used for the gate conductor layer as desired.

The MOL contacts 130, 132 and 134 may be formed by patterning openings or trenches in in the front side ILD layer 126, and filling such openings or trenches with contact material. The contact material may include a silicide layer such as titanium (Ti), nickel (Ni), nickel platinum (NiPt), etc., a metal adhesion layer (e.g., such as TiN) and a low resistance metal such as ruthenium (Ru), tungsten (W), cobalt (Co) or another suitable material. Each of the MOL contacts 130, 132 and 134 may have a width (in the X or Y directions’) in the range of 8 to 50 nm, and a height (in the Z direction) that extends from a bottom surface of the BEOL interconnects 136 to the portion of the structure it contacts. The MOL contacts 130 connect the source/drain regions 124 to the BEOL interconnects 136, and the MOL contacts 134 connect the gate stack layer 128 to the BEOL interconnects 136.

The BEOL interconnects 136 include various BEOL interconnect structures. The carrier wafer 138 may be formed of materials similar to that of the substrate 102, and may be formed over the BEOL interconnects 136 using a wafer bonding process, such as dielectric-to-dielectric bonding.

As shown in FIG. 6A, there are MOL contacts 130 and 132 to the “left” and “right” source/drain regions 124 in the regions where back side transistors will be formed. In FIG. 6B, there is only the MOL contact 130 to the “left” source/drain regions 124. The “right” source/drain region 124 will have a back side contact formed thereto as described in further detail below.

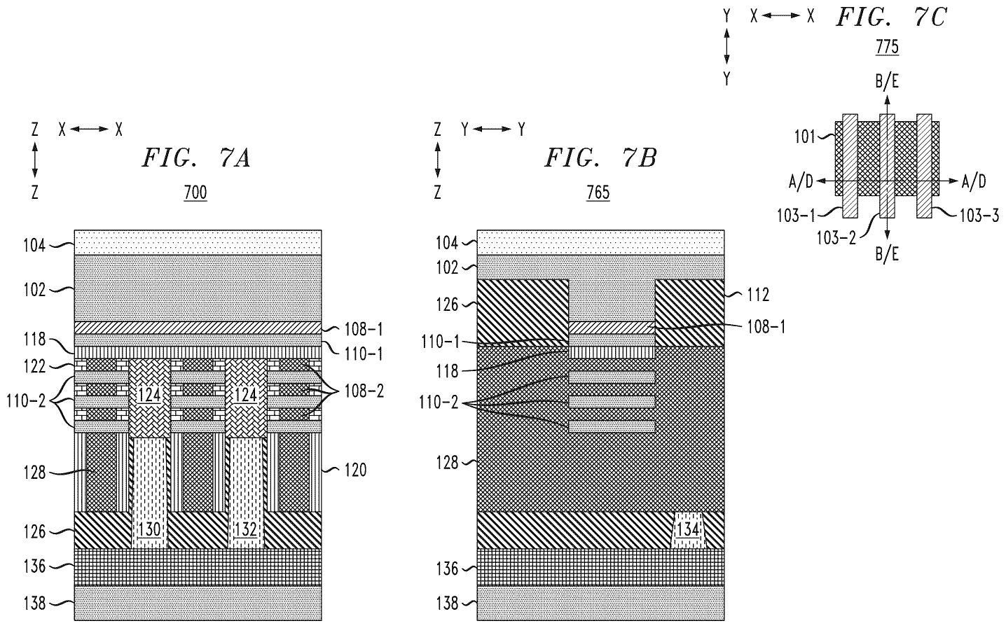

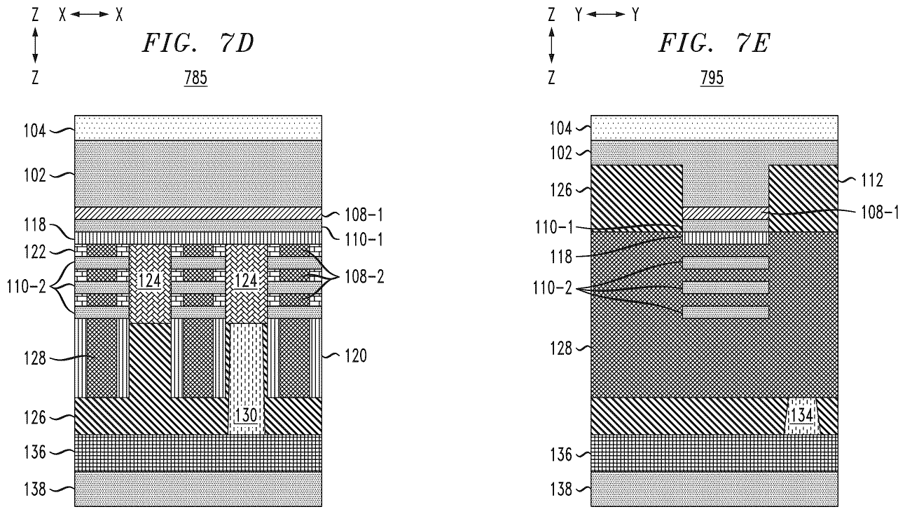

FIG. 7A shows a first side cross-sectional view 700 of the structure of FIGS. 6A-6E following a wafer flip and removal of portions of the substrate 102 stopping on the etch stop layer 104. FIG. 7B shows a second side cross-sectional view 765 of the structure of FIGS. 6A-6E following the wafer flip and the removal of the portions of the substrate 102 stopping on the etch stop layer 104. FIG. 7C shows a top-down view 775 of the structure of FIGS. 6A-6E following the wafer flip and the removal of the portions of the substrate 102 stopping on the etch stop layer 104. FIG. 7D shows a third side cross-sectional view 785 of the structure of FIGS. 6A-6E following the wafer flip and the removal of the portions of the substrate 102 stopping on the etch stop layer 104. FIG. 7E shows a fourth side cross-sectional view 795 of the structure of FIGS. 6A-6E following the wafer flip and the removal of the portions of the substrate 102 stopping on the etch stop layer 104. The first side cross-sectional view 700 of FIG. 7A and the third side cross-sectional view 785 of FIG. 7D are taken along the line A/D-A/D in the top-down view 775 of FIG. 7C, while the second side cross-sectional view 765 of FIG. 7B and the fourth side cross-sectional view 795 of FIG. 7E are taken along the line B/E-B/E in the top-down view 775 of FIG. 7C.

Using the carrier wafer 138, the structure may be “flipped” and portions of the substrate 102 may be removed from the back side. Removal of the portions of the substrate 102 will stop on the etch stop layer 104 as illustrated in FIGS. 7A-7E.

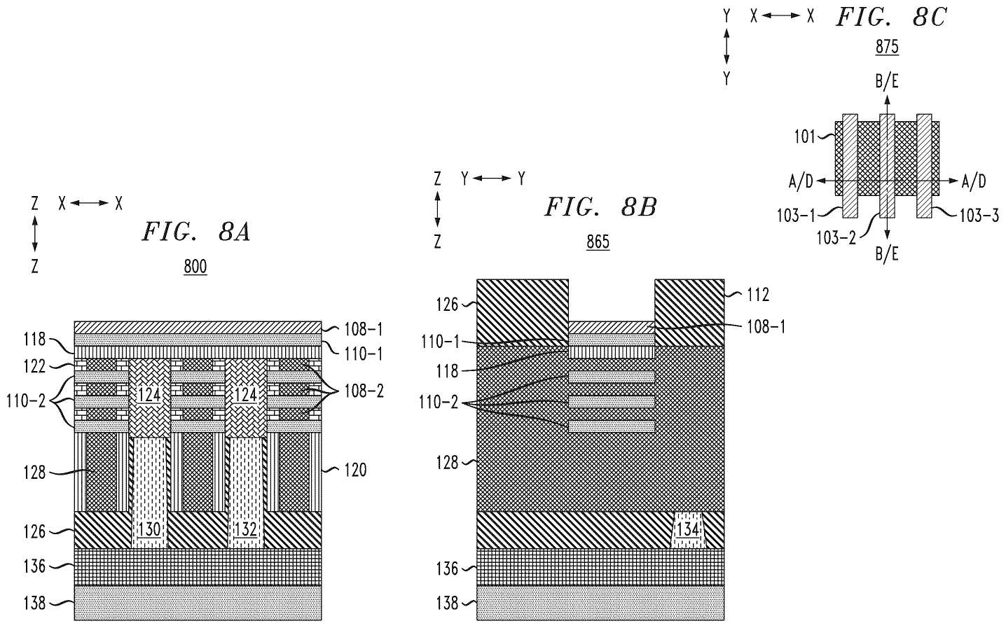

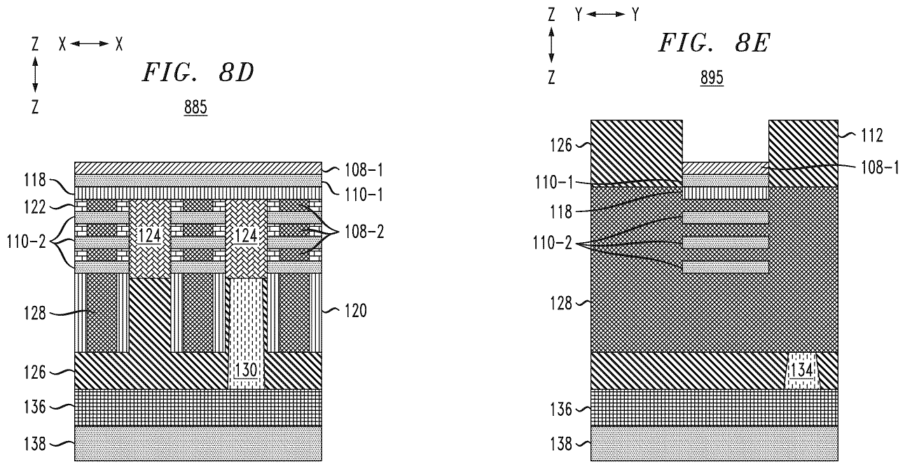

FIG. 8A shows a first side cross-sectional view 800 of the structure of FIGS. 7A-7E following removal of the etch stop layer 104 and remaining portions of the substrate 102. FIG. 8B shows a second side cross-sectional view 865 of the structure of FIGS. 7A-7E following the removal of the etch stop layer 104 and the remaining portions of the substrate 102. FIG. 8C shows a top-down view 875 of the structure of FIGS. 7A-7E following the removal of the etch stop layer 104 and the remaining portions of the substrate 102. FIG. 8D shows a third side cross-sectional view 885 of the structure of FIGS. 7A-7E following the removal of the etch stop layer 104 and the remaining portions of the substrate 102. FIG. 8E shows a fourth side cross-sectional view 895 of the structure of FIGS. 7A-7E following the removal of the etch stop layer 104 and the remaining portions of the substrate 102. The first side cross-sectional view 800 of FIG. 8A and the third side cross-sectional view 885 of FIG. 8D are taken along the line A/D-A/D in the top-down view 875 of FIG. 8C, while the second side cross-sectional view 865 of FIG. 8B and the fourth side cross-sectional view 895 of FIG. 8E are taken along the line B/E-B/E in the top-down view 875 of FIG. 8C.

As shown in FIGS. 8A-8E, the etch stop layer 104 is removed, followed by removal of the remaining portions of the substrate 102 to expose the sacrificial layer 108-1.

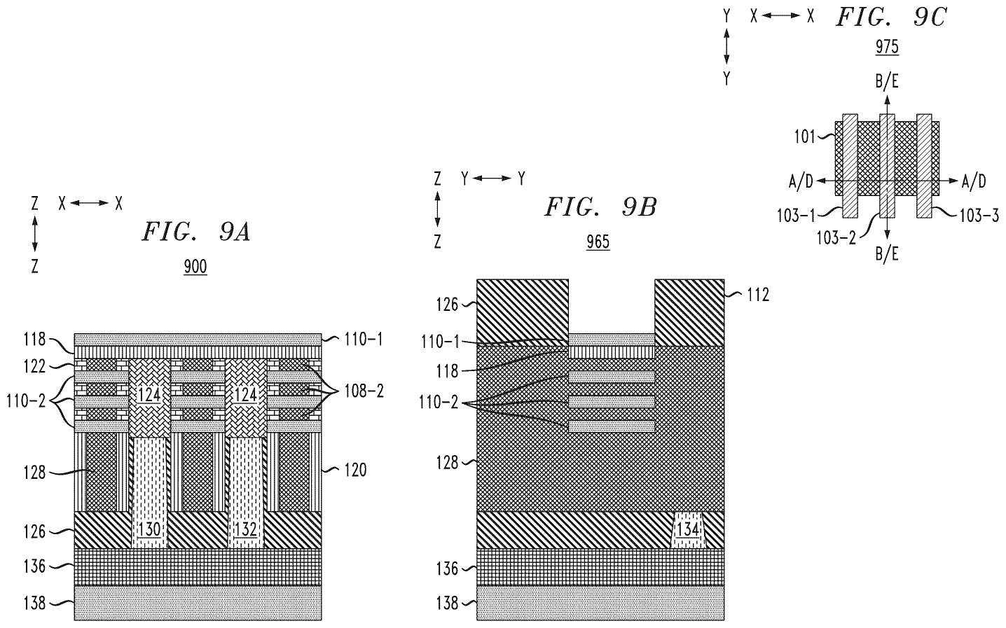

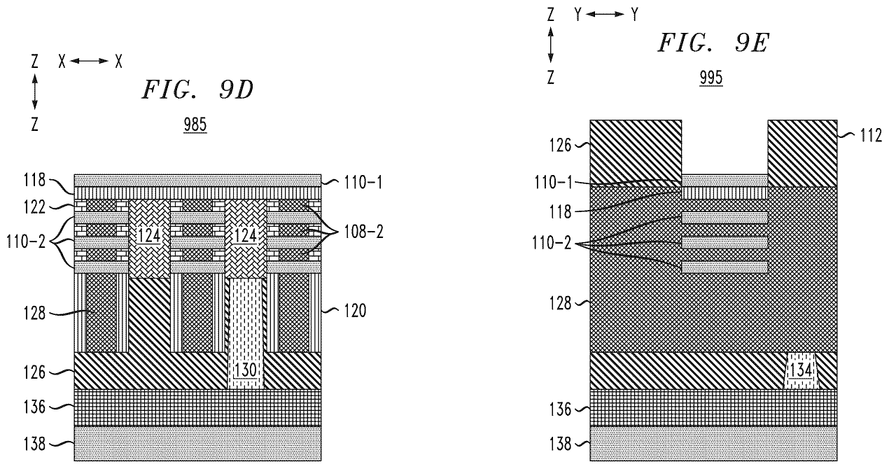

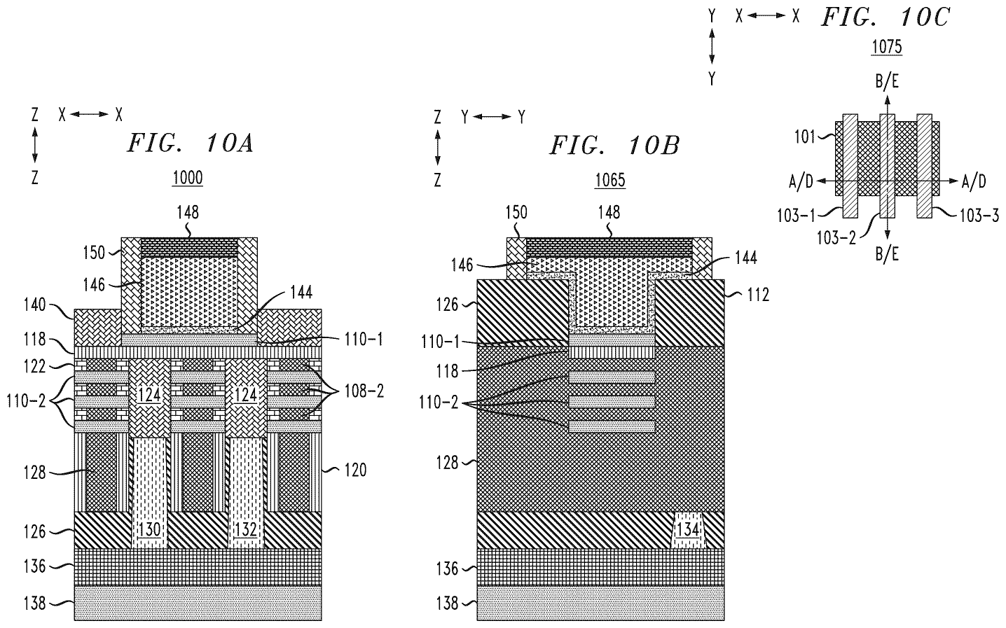

FIG. 9A shows a first side cross-sectional view 900 of the structure of FIGS. 8A-8E following removal of the sacrificial layer 108-1. FIG. 9B shows a second side cross-sectional view 965 of the structure of FIGS. 8A-8E following the removal of the sacrificial layer 108-1. FIG. 9C shows a top-down view 975 of the structure of FIGS. 8A-8E following the removal of the sacrificial layer 108-1. FIG. 9D shows a third side cross-sectional view 985 of the structure of FIGS. 8A-8E following the removal of the sacrificial layer 108-1. FIG. 9E shows a fourth side cross-sectional view 995 of the structure of FIGS. 8A-8E following the removal of the sacrificial layer 108-1. The first side cross-sectional view 900 of FIG. 9A and the third side cross-sectional view 985 of FIG. 9D are taken along the line A/D-A/D in the top-down view 975 of FIG. 9C, while the second side cross-sectional view 965 of FIG. 9B and the fourth side cross-sectional view 995 of FIG. 9E are taken along the line B/E-B/E in the top-down view 975 of FIG. 9C.

As shown in FIGS. 9A-9E, removal of the sacrificial layer 108-1 exposes the channel layer 110-1.

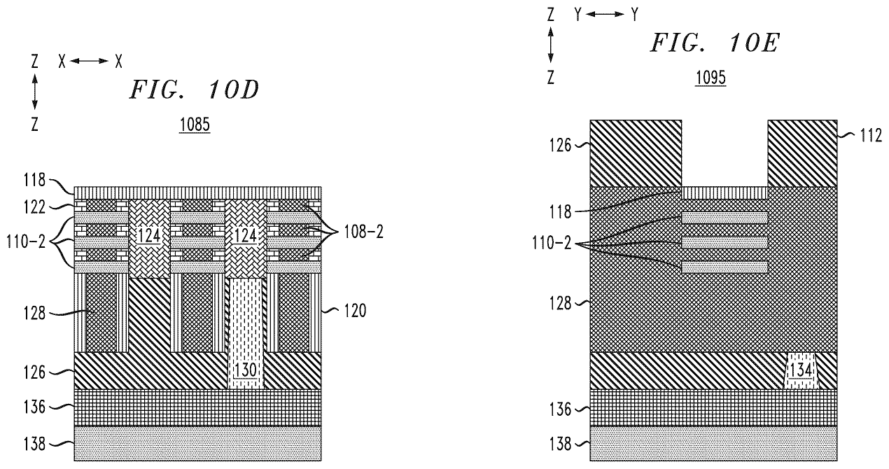

FIG. 10A shows a first side cross-sectional view 1000 of the structure of FIGS. 9A-9E following selective formation of a back side transistor over the channel layer 110-1. FIG. 10B shows a second side cross-sectional view 1065 of the structure of FIGS. 9A-9E following the selective formation of the back side transistor over the channel layer 110-1. FIG. 10C shows a top-down view 1075 of the structure of FIGS. 9A-9E following the selective formation of the back side transistor over the channel layer 110-1. FIG. 10D shows a third side cross-sectional view 1085 of the structure of FIGS. 9A-9E following the selective formation of the back side transistor over the channel layer 110-1. FIG. 10E shows a fourth side cross-sectional view 1095 of the structure of FIGS. 9A-9E following the selective formation of the back side transistor over the channel layer 110-1. The first side cross-sectional view 1000 of FIG. 10A and the third side cross-sectional view 1085 of FIG. 10D are taken along the line A/D-A/D in the top-down view 1075 of FIG. 10C, while the second side cross-sectional view 1065 of FIG. 10B and the fourth side cross-sectional view 1095 of FIG. 10E are taken along the line B/E-B/E in the top-down view 1075 of FIG. 10C.

The back side transistor is formed over the channel layer 110-1 in a first region as shown in FIGS. 10A and 10B, but is not formed over the channel layer 110-1 in a second region as shown in FIGS. 10D and 10E. In the second region shown in FIGS. 10D and 10E, the channel layer 110-1 is removed.

The back side transistor includes source/drain regions 140 and 142, a gate dielectric or gate oxide layer 144, a gate conductor layer 146, a HM layer 148, and a spacer layer 150. Advantageously, the back side transistor has a single-crystal channel layer 110-1 (e.g., single-crystal Si) which has improved performance relative to conventional BEOL TFTs which have polycrystalline channel layers.

The source/drain regions 140 and 142 may be formed using similar processing and materials as the source/drain regions 124. The gate dielectric layer 144 may be formed using similar processing and materials as the gate dielectric of the gate stack layer 128, and the gate conductor layer 146 may be formed using similar processing and materials as the gate conductor of the gate stack layer 128. The gate dielectric layer 144 may have a uniform thickness in the range of 2-15 nm. The gate conductor layer 146 may have a height (in the Z direction) in the range of 15 to 100 nm, and may have a width (in the X direction) in the range of 20 to 200 nm. The HM layer 148 may be formed using similar processing and materials as the gate HM layer 116. The HM layer 148 may have a height (in the Z direction) in the range of 10 to 40 nm. The spacer layer 150 may be formed of SiN, SiBCN, SiOCN, SiOC or another suitable material, and may have a width (in the X and Y directions) in the range of 5 to 20 nm.

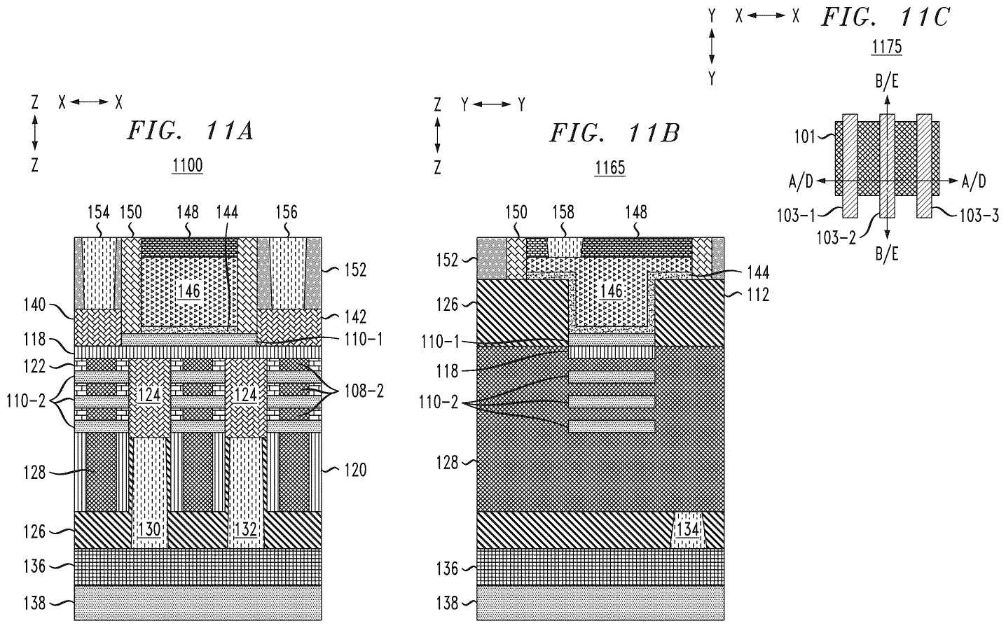

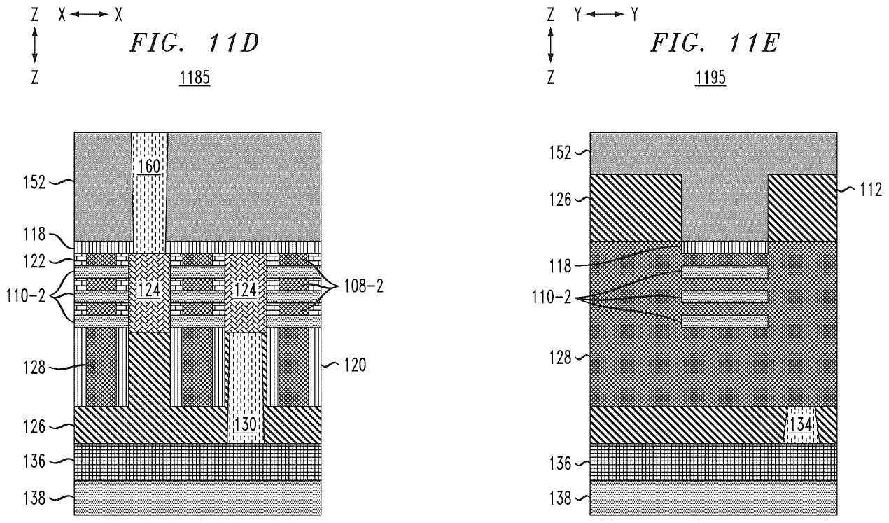

FIG. 11A shows a first side cross-sectional view 1100 of the structure of FIGS. 10A-10E following formation of a back side ILD layer 152 and formation of contacts therethrough. FIG. 11B shows a second side cross-sectional view 1165 of the structure of FIGS. 10A-10E following the formation of the back side ILD layer 152 and the formation of the contacts therethrough. FIG. 11C shows a top-down view 1175 of the structure of FIGS. 10A-10E following the formation of the back side ILD layer 152 and the formation of the contacts therethrough. FIG. 11D shows a third side cross-sectional view 1185 of the structure of FIGS. 10A-10E following the formation of the back side ILD layer 152 and the formation of the contacts therethrough. FIG. 11E shows a fourth side cross-sectional view 1195 of the structure of FIGS. 10A-10E following the formation of the back side ILD layer 152 and the formation of the contacts therethrough. The first side cross-sectional view 1100 of FIG. 11A and the third side cross-sectional view 1185 of FIG. 11D are taken along the line A/D-A/D in the top-down view 1175 of FIG. 11C, while the second side cross-sectional view 1165 of FIG. 11B and the fourth side cross-sectional view 1195 of FIG. 11E are taken along the line B/E-B/E in the top-down view 1175 of FIG. 11C.

The back side ILD layer 152 may be deposited and planarized (e.g., using CMP or other suitable processing). The back side ILD layer 152 may be formed of similar materials as the front side ILD layer 126. Openings are then patterned in the back side ILD layer 152 and HM layer 148, and contacts 154, 156, and 158 in such opening are formed as shown in FIGS. 11A and 11B. An opening is also patterned in the back side ILD layer 152 and BDI layer 118 to expose one of the source/drain regions 124 (e.g., which does not have the MOL contact 130), and contact 160 is formed in this opening. The contacts 154 and 156 connect to the source/drain regions 140 and 142, respectively, while the contact 158 connects to the gate conductor layer 146. The contact 160 is formed through the back side ILD layer 152 and the BDI layer 118 to connect to the source/drain region 124 (e.g., which does not have the MOL contact 130). The contacts 154, 156, 158 and 160 may be formed of similar material and with similar sizing and processing as the MOL contacts 130, 132 and 134.

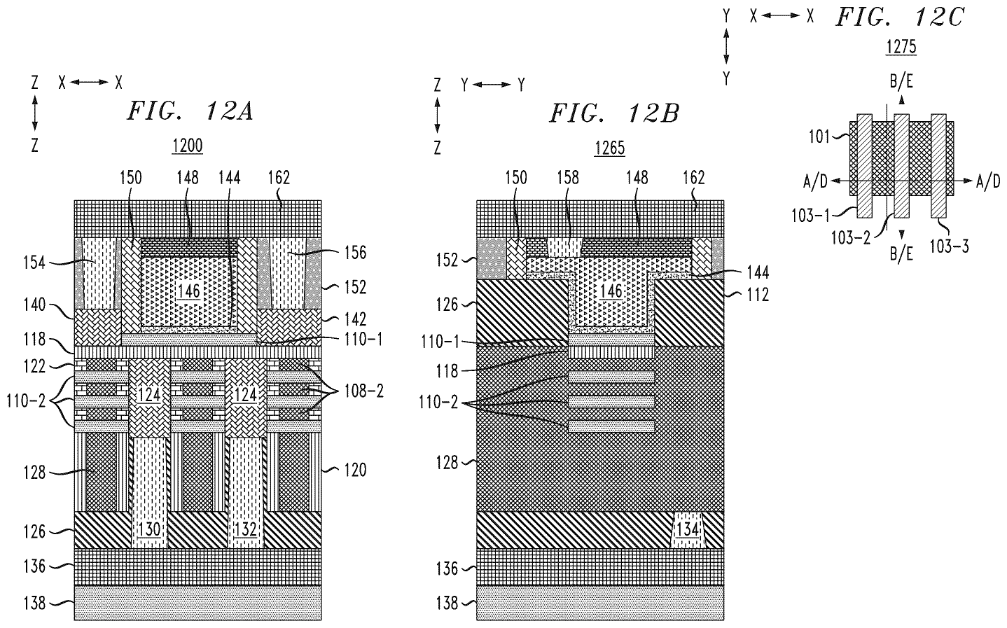

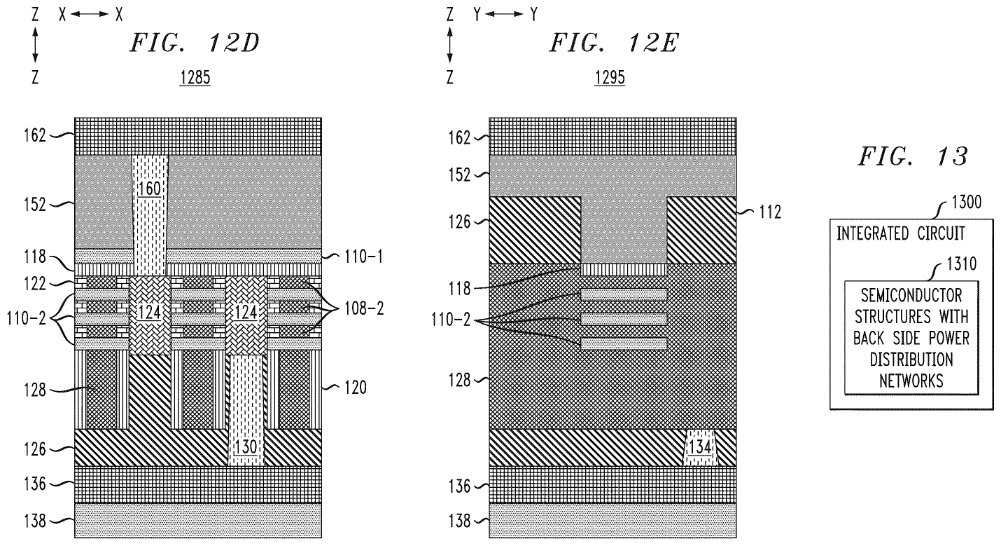

FIG. 12A shows a first side cross-sectional view 1200 of the structure of FIGS. 11A-11E following formation of back side BEOL interconnects 162. FIG. 12B shows a second side cross-sectional view 1265 of the structure of FIGS. 11A-11E following the formation of the back side BEOL interconnects 162. FIG. 12C shows a top-down view 1275 of the structure of FIGS. 11A-11E following the formation of the back side BEOL interconnects 162. FIG. 12D shows a third side cross-sectional view 1285 of the structure of FIGS. 11A-11E following the formation of the back side BEOL interconnects 162. FIG. 12E shows a fourth side cross-sectional view 1295 of the structure of FIGS. 11A-11E following the formation of the back side BEOL interconnects 162. The first side cross-sectional view 1200 of FIG. 12A and the third side cross-sectional view 1285 of FIG. 12D are taken along the line A/D-A/D in the top-down view 1275 of FIG. 12C, while the second side cross-sectional view 1265 of FIG. 12B and the fourth side cross-sectional view 1295 of FIG. 12E are taken along the line B/E-B/E in the top-down view 1275 of FIG. 12C.

The back side BEOL interconnects 162 may be formed with similar sizing and composition as that of the front side BEOL interconnects 136.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, complementary metal-oxide-semiconductors (CMOSs), metal-oxide-semiconductor field-effect transistors (MOSFETs), and/or fin field-effect transistors (FinFETs). By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor. FIG. 13 shows an example integrated circuit 1300 which includes one or more semiconductor structures 1310 with BSPDNs.

In some embodiments, a semiconductor structure comprises one or more transistor devices on a first side of the semiconductor structure, one or more transistor devices on a second side of the semiconductor structure, the second side being opposite the first side, and a dielectric isolation layer separating the one or more transistor devices on the first side of the semiconductor structure from the one or more transistor devices on the second side of the semiconductor structure. The one or more transistor devices on the second side of the semiconductor structure comprise channel layers on one side of the dielectric isolation layer and source/drain regions that are independent of source/drain regions of the one or more transistor devices on the first side of the semiconductor structure.

The one or more transistor devices on the first side of the semiconductor structure may comprise nanosheet FET devices. The channel layers of the one or more transistor devices on the second side of the semiconductor structure have a first channel length greater than a second channel length of nanosheet channel layers of the one or more transistor devices on the first side of the semiconductor structure.

The channel layers of the one or more transistor devices on the second side of the semiconductor structure may comprise a single-crystal semiconductor material.

The channel layers of the one or more transistor devices on the second side of the semiconductor structure may comprise single-crystal silicon.

The one or more transistor devices on the second side of the semiconductor structure may be disposed on a first side of a first subset of the one or more transistor devices on the first side of the semiconductor structure, and the semiconductor structure may further comprise one or more contacts disposed on the first side of a second subset of the one or more transistor devices on the first side of the semiconductor structure. The one or more contacts may connect to one or more of the source/drain regions of one or more of the transistor devices on the first side of the semiconductor structure that are in the second subset. The one or more transistor devices on the second side of the semiconductor structure are not disposed on the first side of the second subset of the one or more transistor devices on the first side of the semiconductor structure.

The one or more transistor devices on the second side of the semiconductor structure may comprise long channel transistors.

The one or more transistor devices on the second side of the semiconductor structure may comprise thick gate oxide transistor devices.

In some embodiments, an integrated circuit comprises a semiconductor structure comprising one or more transistor devices on a first side of the semiconductor structure, one or more transistor devices on a second side of the semiconductor structure, the second side being opposite the first side, and a dielectric isolation layer separating the one or more transistor devices on the first side of the semiconductor structure from the one or more transistor devices on the second side of the semiconductor structure. The one or more transistor devices on the second side of the semiconductor structure comprise channel layers on one side of the dielectric isolation layer and source/drain regions that are independent of source/drain regions of the one or more transistor devices on the first side of the semiconductor structure.

The one or more transistor devices on the first side of the semiconductor structure may comprise nanosheet FET devices, and the channel layers of the one or more transistor devices on the second side of the semiconductor structure may have a first channel length greater than a second channel length of nanosheet channel layers of the one or more transistor devices on the first side of the semiconductor structure.

The channel layers of the one or more transistor devices on the second side of the semiconductor structure may comprise a single-crystal semiconductor material.

The one or more transistor devices on the second side of the semiconductor structure may be disposed on a first side of a first subset of the one or more transistor devices on the first side of the semiconductor structure, and the semiconductor structure may further comprise one or more contacts disposed on the first side of a second subset of the one or more transistor devices on the first side of the semiconductor structure.

The one or more contacts may connect to one or more of the source/drain regions of one or more of the transistor devices on the first side of the semiconductor structure that are in the second subset.

In some embodiments, a method comprises forming one or more transistor devices on a first side of a semiconductor structure, forming one or more transistor devices on a second side of the semiconductor structure, the second side being opposite the first side, and forming a dielectric isolation layer separating the one or more transistor devices on the first side of the semiconductor structure from the one or more transistor devices on the second side of the semiconductor structure. The one or more transistor devices on the second side of the semiconductor structure comprise channel layers on one side of the dielectric isolation layer and source/drain regions that are independent of source/drain regions of the one or more transistor devices on the first side of the semiconductor structure.

Nanosheet channel layers of the one or more transistor devices on the first side of the semiconductor structure are formed on a first side of the dielectric isolation layer and the channel layers of the one or more transistor devices on the second side of the semiconductor structure are formed on a second side of the dielectric isolation layer, and the channel layers of the transistor devices on the second side of the semiconductor structure are separated from a substrate by a sacrificial layer.

The channel layers of the one or more transistor devices on the second side of the semiconductor structure may be formed from a semiconductor layer formed between the dielectric isolation layer and a substrate, wherein a sacrificial layer separates the substrate from the semiconductor layer.

Forming the one or more transistor devices on the second side of the semiconductor structure may comprise performing a wafer flip of the substrate, removing the substrate, removing the sacrificial layer to expose the semiconductor layer, forming the channel layers of the one or more transistor devices on the second side of the semiconductor structure from portions of the semiconductor layer disposed on a first side of a first subset of the one or more transistor devices on the first side of the semiconductor structure, and removing portions of the semiconductor layer disposed on the first side of a second subset of the one or more transistor devices on the first side of the semiconductor structure. The method may further comprise forming one or more contacts that connect to one or more of the source/drain regions of one or more of the transistor devices on the first side of the semiconductor structure that are in the second subset.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure comprising:
one or more transistor devices on a first side of the semiconductor structure;
one or more transistor devices on a second side of the semiconductor structure, the second side being opposite the first side; and
a dielectric isolation layer separating the one or more transistor devices on the first side of the semiconductor structure from the one or more transistor devices on the second side of the semiconductor structure;
wherein the one or more transistor devices on the second side of the semiconductor structure comprise channel layers on one side of the dielectric isolation layer and source/drain regions that are independent of source/drain regions of the one or more transistor devices on the first side of the semiconductor structure.

2. The semiconductor structure of claim 1, wherein the one or more transistor devices on the first side of the semiconductor structure comprise nanosheet field-effect transistor devices.

3. The semiconductor structure of claim 2, wherein the channel layers of the one or more transistor devices on the second side of the semiconductor structure have a first channel length greater than a second channel length of nanosheet channel layers of the one or more transistor devices on the first side of the semiconductor structure.

4. The semiconductor structure of claim 1, wherein the channel layers of the one or more transistor devices on the second side of the semiconductor structure comprise a single-crystal semiconductor material.

5. The semiconductor structure of claim 1, wherein the channel layers of the one or more transistor devices on the second side of the semiconductor structure comprise single-crystal silicon.

6. The semiconductor structure of claim 1, wherein the one or more transistor devices on the second side of the semiconductor structure are disposed on a first side of a first subset of the one or more transistor devices on the first side of the semiconductor structure, and further comprising one or more contacts disposed on the first side of a second subset of the one or more transistor devices on the first side of the semiconductor structure.

7. The semiconductor structure of claim 6, wherein the one or more contacts connect to one or more of the source/drain regions of one or more of the transistor devices on the first side of the semiconductor structure that are in the second subset.

8. The semiconductor structure of claim 6, wherein the one or more transistor devices on the second side of the semiconductor structure are not disposed on the first side of the second subset of the one or more transistor devices on the first side of the semiconductor structure.

9. The semiconductor structure of claim 1, wherein the one or more transistor devices on the second side of the semiconductor structure comprise long channel transistors.

10. The semiconductor structure of claim 1, wherein the one or more transistor devices on the second side of the semiconductor structure comprise thick gate oxide transistor devices.

11. An integrated circuit comprising:
a semiconductor structure comprising:
one or more transistor devices on a first side of the semiconductor structure;
one or more transistor devices on a second side of the semiconductor structure, the second side being opposite the first side; and
a dielectric isolation layer separating the one or more transistor devices on the first side of the semiconductor structure from the one or more transistor devices on the second side of the semiconductor structure;
wherein the one or more transistor devices on the second side of the semiconductor structure comprise channel layers on one side of the dielectric isolation layer and source/drain regions that are independent of source/drain regions of the one or more transistor devices on the first side of the semiconductor structure.

12. The integrated circuit of claim 11, wherein the one or more transistor devices on the first side of the semiconductor structure comprise nanosheet field-effect transistor devices, and wherein the channel layers of the one or more transistor devices on the second side of the semiconductor structure have a first channel length greater than a second channel length of nanosheet channel layers of the one or more transistor devices on the first side of the semiconductor structure.

13. The integrated circuit of claim 11, wherein the channel layers of the one or more transistor devices on the second side of the semiconductor structure comprise a single-crystal semiconductor material.

14. The integrated circuit of claim 11, wherein the one or more transistor devices on the second side of the semiconductor structure are disposed on a first side of a first subset of the one or more transistor devices on the first side of the semiconductor structure, and further comprising one or more contacts disposed on the first side of a second subset of the one or more transistor devices on the first side of the semiconductor structure.

15. The integrated circuit of claim 14, wherein the one or more contacts connect to one or more of the source/drain regions of one or more of the transistor devices on the first side of the semiconductor structure that are in the second subset.

16. A method comprising:
forming one or more transistor devices on a first side of a semiconductor structure;
forming one or more transistor devices on a second side of the semiconductor structure, the second side being opposite the first side; and
forming a dielectric isolation layer separating the one or more transistor devices on the first side of the semiconductor structure from the one or more transistor devices on the second side of the semiconductor structure;
wherein the one or more transistor devices on the second side of the semiconductor structure comprise channel layers on one side of the dielectric isolation layer and source/drain regions that are independent of source/drain regions of the one or more transistor devices on the first side of the semiconductor structure.

17. The method of claim 16, wherein nanosheet channel layers of the one or more transistor devices on the first side of the semiconductor structure are formed on a first side of the dielectric isolation layer and the channel layers of the one or more transistor devices on the second side of the semiconductor structure are formed on a second side of the dielectric isolation layer, the channel layers of the transistor devices on the second side of the semiconductor structure are separated from a substrate by a sacrificial layer.

18. The method of claim 16, wherein the channel layers of the one or more transistor devices on the second side of the semiconductor structure are formed from a semiconductor layer formed between the dielectric isolation layer and a substrate, wherein a sacrificial layer separates the substrate from the semiconductor layer.

19. The method of claim 18, wherein forming the one or more transistor devices on the second side of the semiconductor structure comprises:
performing a wafer flip of the substrate;
removing the substrate;
removing the sacrificial layer to expose the semiconductor layer;
forming the channel layers of the one or more transistor devices on the second side of the semiconductor structure from portions of the semiconductor layer disposed on a first side of a first subset of the one or more transistor devices on the first side of the semiconductor structure; and
removing portions of the semiconductor layer disposed on the first side of a second subset of the one or more transistor devices on the first side of the semiconductor structure.

20. The method of claim 19, further comprising forming one or more contacts that connect to one or more of the source/drain regions of one or more of the transistor devices on the first side of the semiconductor structure that are in the second subset.
